(19) United States
(12) Patent Application Publication
(10) Pub. No.: US 2020/0114353 A1
(43) Pub. Date: Apr. 16, 2020

(54) Low-Cost Microfluidic Sensors with Smart Hydrogel Patterned Arrays Using Electronic Resistive Channel Sensing for Readout

(71) Applicant: University of Utah Research Foundation, Salt Lake City, UT (US)

(72) Inventors: Hsuan-Yu Leu, Salt Lake City, UT (US); Navid Farhoudi, Salt Lake City, UT (US); Christopher F. Reiche, Salt Lake City, UT (US); Julia Koerner, Salt Lake City, UT (US); Swomitra Kumar Mohanty, Salt Lake City, UT (US); Florian Solzbacher, Salt Lake City, UT (US); Jules John Magda, Salt Lake City, UT (US)

(21) Appl. No.: 16/601,120

(22) Filed: Oct. 14, 2019

Related U.S. Application Data
(60) Provisional application No. 62/745,894, filed on Oct. 15, 2018.

(51) Int. Cl. B01L 3/00; G03F 7/20; G01N 27/12

(52) U.S. Cl. CPC B01L 3/502715; G03F 7/70; G01N 27/128; B01L 2200/02; B33Y 10/00; B01L 2300/0809; B01L 2300/12; B01L 2300/0832; B01L 2300/0645

(57) ABSTRACT

Microfluidics sensor devices having an array of smart polymer hydrogel features for resistive channel analyte sensing via hydrogel swelling and de-swelling, and methods of manufacturing and using the same. Inexpensive, rapid-responsive, point-of-use sensors for monitoring disease biomarkers or environmental contaminants in, for example, drinking water, employ smart polymer hydrogels as recognition elements that can be tailored to detect almost any target analyte. Fabrication involves mask-templated UV photopolymerization to produce an array of smart hydrogel pillars, with large surface area-to-volume ratios, inside sub-millimeter channels located on microfluidics devices. The pillars swell or shrink upon contact aqueous solutions containing a target analyte, thereby changing the resistance of the microfluidic channel to ionic current flow when a bias voltage is applied to the system. Hence resistance measurements can be used to transduce hydrogel swelling changes into electrical signals. A portable potentiostat can be included to make the system suitable for point of use.

### CROSS-REFERENCE TO RELATED APPLICATIONS

This application claims the benefit of and priority to U.S. Provisional Patent Application Ser. No. 62/745,894, filed Oct. 15, 2018, entitled LOW-COST MICROFLUIDIC SENSORS WITH SMART HYDROGEL PATTERNED ARRAYS USING ELECTRONIC RESISTIVE CHANNEL SENSING FOR READOUT, the entirety of which is incorporated by reference herein.

### BACKGROUND

### 1. Technical Field

The present disclosure relates to the field of microfluidic sensors, and particularly microfluidic sensors incorporating smart hydrogel features. In particular, the present disclosure relates to microfluidic sensor devices having one or more microfluidic channel with an array of smart hydrogel features arranged therein for resistive channel analyte sensing via hydrogel swelling and de-swelling, and to methods of manufacturing and using the same. Preferably, the devices are manufactured using simple and/or low-cost fabrication materials and techniques.

### 2. Related Technology

A smart polymer hydrogel is a cross-linked polymer network that autonomously and reversibly swells or shrinks in response to some environment signal, such as change in the concentration of a target analyte, such as, for example, glucose. Smart polymer hydrogels can be chemically tailored to selectively respond to many different analytes, but swelling response time is often a limiting factor for their use in sensing applications. In addition, chemical sensors are often manufactured from high cost materials or through costly manufacturing methods.

Accordingly, there are a number of problems in the field of immunoassay generation for small molecules, including immunoassays for mitragynine detection, that can be addressed.

### BRIEF DESCRIPTION OF THE DRAWINGS

Various embodiments of the present invention will now be discussed with reference to the appended drawings. It is appreciated that these drawings depict only typical embodiments of the invention and are therefore not to be considered limiting of its scope.

FIG. 1 illustrates an assembly of microfluidics device for in situ patterning of smart hydrogels;

FIG. 2 illustrates patterning of hydrogel pillars in a microfluidic channel to form a microfluidics sensing device according to an embodiment of the present disclosure;

FIG. 3 illustrates a microfluidics sensing device according to another embodiment of the present disclosure;

FIG. 4 illustrates a top-down view of an array of smart hydrogel pillars fabricated by passing UV light through a mask containing an array of circular apertures of diameter 100 μm. (A) Smart hydrogel pillars surrounded by 1/12× PBS solution at pH 7.5 (B) Enlarged photograph showing the increase in pillar diameter that occurs when the pH value is increased from 7.5 to 10.5;

FIG. 5 illustrates a time-dependent value of the sensor ionic current (A, B) and the signal response % (C, D) for periodic changes in pH between 7.5 and 10.5. The pillar diameter as defined by the UV mask was 100 μm (A, C) or 300 μm (B, D). In (C), the signal response % has been corrected for baseline drift;

FIG. 6 illustrates the effect of pillar diameter upon the T90 response time of the microfluidic sensor, as calculated using the response data given in FIG. 4. Comparison is made between the results obtained using pillars of diameter 100 μm and 300 μm with surface area-to-volume ratios of 40 mm⁻¹ and 13.3 mm⁻¹, respectively. As expected, the response time is substantially smaller for the sensor that utilizes smaller diameter pillars;

FIG. 7 illustrates a top-down view of an illustrative array of smart hydrogel pillars showing the size change due to changes in environmental ionic strength: (A) smaller diameter smart hydrogel pillars surrounded by 1× PBS solution. (B) larger diameter smart hydrogel pillars surrounded by 0.33× PBS solution.

FIG. 8 illustrates smart hydrogel pillars before (A) and after (B) shrinking in response to stimulus; and

FIG. 9 illustrates a schematic of a microfluidics sensing device with smart hydrogel for detecting analytes of interest in solution using resistive channel sensing (RCS).

### BRIEF SUMMARY

This summary is provided to introduce a selection of concepts in a simplified form and that are further described below in the Detailed Description and appended claims, which form a part of the present disclosure. This Summary is not intended to identify key features or essential features of the claimed subject matter, nor is it intended to be used to restrict the scope of the claimed subject matter.

The present disclosure relates to the field of microfluidic sensors, and particularly microfluidic sensors incorporating smart hydrogel features. In particular, embodiments of the present disclosure relate to microfluidic sensor devices having one or more microfluidic channel with an array of smart hydrogel features (e.g., pillars) arranged therein for resistive channel analyte sensing via hydrogel swelling and de-swelling, and to methods of manufacturing and using the same. Preferably, the devices are manufactured using simple and/or low-cost fabrication materials and techniques.

Some embodiments of the present disclosure relate to the use of mask-templated UV photopolymerization to produce (microscopic) smart hydrogel features, preferably with large surface area-to-volume ratios and, consequently, fast response rates. Arrays of smart hydrogel features (e.g., pillars), preferably spaced regularly one from another, can be fabricated inside sub-millimeter channels located within microfluidics devices. For potential use in chemical sensing, microfluidic devices offer advantages such as potentially being low cost and requiring only small sample volumes. The sensor response time is shown to decrease with an increase in surface area-to-volume ratio.

A continuous chemical sensor can be obtained by combining a smart polymer hydrogel with a means for transducing hydrogel swelling changes into electrical signals. However, while smart polymer hydrogels can be chemically tailored to selectively respond to many different analytes, swelling response time is often a limiting factor for their use in sensing applications. Given that the rate of analyte mass transfer is often the rate-determining step in hydrogel response, the present disclosure is based, at least in part, on the proposition that shorter response times can be achieved by fabricating smart hydrogels with large surface area-to-volume ratios. Accordingly, the present disclosure solves one or more of the foregoing or other problems in the art with microfluidic devices (e.g., sensors) having one or more microfluidic channel(s) with an array of microscopic smart hydrogel pillars with large surface area-to-volume ratios arranged in the microfluidic channel(s) for resistive channel analyte sensing via hydrogel swelling and de-swelling.

Some embodiments of the present disclosure include a method of sensing an analyte of interest. Illustratively, the method can comprise applying a current or voltage across a microfluidic channel of a microfluidics sensor device. The microfluidic channel can comprise (or have disposed therein) an ion-conducting or electrically conductive fluid medium and an array of smart hydrogel features disposed in the medium. The method can include introducing a fluid sample into the microfluidic channel. The fluid sample can comprise an analyte for interest. The analyte can be or comprise, a molecule, compound, contaminant, drug, mineral, element, or other matter to be detected and/or quantified in the sample. The method can include measuring a change in an output reading of the applied current or voltage as the array of smart hydrogel features is exposed to the analyte. Exposing the array of smart hydrogel features to the analyte can cause a change in size of one or more of the smart hydrogel features. The change in the size of the one or more smart hydrogel features can cause a change in resistance across the microfluidic channel. The change in resistance across the microfluidic channel can cause the change in the output reading of the applied current or voltage. The change in the output reading of the applied current or voltage can indicate presence of the analyte in the sample.

In some embodiments, (each of) the smart hydrogel features in the array has a surface area-to-volume ratio greater than or equal to 13.3 mm⁻¹ (e.g., 40 mm⁻¹ or more). In some embodiments, the array comprises a plurality of spaced-apart smart hydrogel pillars. In some embodiments, the pillars are substantially cylindrical, each of the pillars optionally having a diameter of less than or equal to about 300 μm and/or being separated from a nearest neighboring pillar by at least 50 μm. In other embodiments, the pillars can be or have oval, squared, rectangular, and/or rounded cross-sectional configurations or shapes. In some embodiments, about 10% to about 30% of microfluidic channel volume or area is occupied by the smart hydrogel features. In some embodiments, the microfluidic channel comprises an at least partially tubular or enclosed conduit, the smart hydrogel features extending across the conduit.

In some embodiments, introducing the analyte into the microfluidic channel changes pH of the medium, thereby causing the change in the size of the one or more smart hydrogel features. In some embodiments, the applied current or voltage is a fixed voltage and the change in the output reading of the applied current or voltage is a change in a value of ionic current. The change in the value of the ionic current can be detected by a potentiostat applying the fixed voltage. In some embodiments, the medium comprises an aqueous salt solution. In some embodiments, the method further comprises continuously flowing the medium through the microfluidic channel.

In some embodiments, a method of sensing an analyte comprises exposing the analyte to an array of smart hydrogel features disposed in a microfluidic channel and measuring a change in a current or voltage bias across the microfluidic channel, wherein the change in the current or voltage bias indicates exposure of the array of smart hydrogel features to the analyte.

Some embodiments include a microfluidics sensor device, comprising a microfluidic channel having an array of smart hydrogel features disposed therein. In some embodiments, in the microfluidics sensor device, each of the smart hydrogel features in the array has a surface area-to-volume ratio greater than or equal to 13.3 mm⁻¹. In some embodiments, each of the smart hydrogel features is optionally separated from a nearest neighboring smart hydrogel features by at least 50 μm. In some embodiments, about 10% to about 30% of microfluidic channel volume or area is occupied by the smart hydrogel features. In some embodiments, the array comprises a plurality of spaced-apart smart hydrogel pillars, the pillars optionally being substantially cylindrical, each of the pillars optionally having a diameter of less than or equal to about 300 μm.

Some embodiments include a method of manufacturing a microfluidics sensor device (as described). The method can comprise introducing a fluid and/or pre-gel hydrogel solution into the microfluidic channel, positioning a photomask over the microfluidic channel, the photomask comprising an array of apertures, directing collimated UV light through the apertures an into the microfluidic channel for a first period of time, thereby at least partially polymerizing portions of the hydrogel to form the array of smart hydrogel features within the microfluidic channel, removing the photomask, exposing the microfluidic channel to UV light for a second period of time, and irrigating the microfluidic channel to remove unpolymerized hydrogel, thereby forming the array of smart hydrogel features within the microfluidic channel. In some embodiments, the first period is about 3 seconds to about 8 seconds and the second period is about 10% to about 40% of the first period.

In some embodiments, the method further comprises 3D printing a bottom layer of the microfluidics sensor device, the bottom layer comprising a microchannel and covering the microchannel with a non-opaque top layer, thereby forming the microfluidic channel. In some embodiments, the bottom layer comprises a first, electrically non-conductive polymer and a second, electrically conductive polymer, the second polymer intersecting the microchannel so as to be in electrical communication therewith. In some embodiments, the first polymer and/or the second polymer comprises a polylactic acid (PLA). In some embodiments, the bottom layer comprises a first electrode disposed at a first end of the microchannel and a second electrode disposed at an opposing second end of the microchannel, the first electrode and the second electrode comprising an electrically conductive polymer, optionally comprising a polylactic acid (PLA). In some embodiments, the microchannel is raised above an upper surface of the bottom layer. In other embodiments, the microchannel is recessed into or below the upper surface of the bottom layer.

These and other aspects, features, embodiments, and/or implementations of the present disclosure, and of the invention(s) disclosed and described herein, will become more fully apparent from the following description and appended claims, or may be learned by the practice of the embodiments and/or invention(s) as set forth hereinafter.

### DETAILED DESCRIPTION

Example embodiments are described below. Many different forms and embodiments are possible without deviating from the spirit and teachings of this disclosure and so the disclosure should not be construed as limited to the example embodiments set forth herein. Rather, these example embodiments are provided so that this disclosure will be thorough and complete, and will convey the scope of the disclosure to those skilled in the art.

Unless defined otherwise, all terms (including technical and scientific terms) used herein have the same meaning as commonly understood by one of ordinary skill in the art to which the present disclosure pertains. It will be further understood that terms, such as those defined in commonly used dictionaries, should be interpreted as having a meaning that is consistent with their meaning in the context of the present application and relevant art and should not be interpreted in an idealized or overly formal sense unless expressly so defined herein. In case of a conflict in terminology, the present specification is controlling.

The terminology used in the description of the invention herein is for the purpose of describing particular embodiments only and is not intended to be limiting of the invention. While a number of methods and materials similar or equivalent to those described herein can be used in the practice of the present disclosure, only certain exemplary materials and methods are described herein.

Various aspects of the present disclosure, including devices, systems, methods, etc., may be illustrated with reference to one or more exemplary implementations. As used herein, the terms “exemplary” and “illustrative” mean “serving as an example, instance, or illustration,” and should not necessarily be construed as preferred or advantageous over other implementations disclosed herein. In addition, reference to an “implementation” or “embodiment” of the present disclosure or invention includes a specific reference to one or more embodiments thereof, and vice versa, and is intended to provide illustrative examples without limiting the scope of the invention, which is indicated by the appended claims rather than by the following description.

It will be noted that, as used in this specification and the appended claims, the singular forms “a,” “an,” and “the” include plural referents unless the content clearly dictates otherwise. Thus, for example, reference to “a tile” includes one, two, or more tiles. Similarly, reference to a plurality of referents should be interpreted as comprising a single referent and/or a plurality of referents unless the content and/or context clearly dictate otherwise. Thus, reference to “tiles” does not necessarily require a plurality of such tiles. Instead, it will be appreciated that independent of conjugation; one or more tiles are contemplated herein.

Moreover, the word “or” as used herein means any one member of a particular list and also includes any combination of members of that list.

As used throughout this application the words “can” and “may” are used in a permissive sense (i.e., meaning having the potential to), rather than the mandatory sense (i.e., meaning must). Additionally, the terms “including,” “having,” “involving,” “containing,” “characterized by,” variants thereof (e.g., “includes,” “has,” “involves,” “contains,” etc.), and similar terms as used herein, including the claims, shall be inclusive and/or open-ended, shall have the same meaning as the word “comprising” and variants thereof (e.g., “comprise” and “comprises”), and do not exclude additional, un-recited elements or method steps, illustratively.

It will be understood that although the terms “first,” “second,” etc. may be used herein to describe various elements, these elements should not be limited by these terms. These terms are only used to distinguish one element from another. Thus, a “first” element could be termed a “second” element without departing from the teachings of the present embodiments.

It is also understood that various features, embodiments, and/or implementations described herein can be utilized in combination with any other feature, embodiment, and/or implementation described or disclosed, without departing from the scope of the present disclosure. Therefore, products, members, elements, devices, apparatuses, kits, systems, methods, processes, compositions, and/or formulations according to certain embodiments and/or implementations of the present disclosure can include, incorporate, or otherwise comprise properties, features, components, members, elements, steps, and/or the like described in other embodiments and/or implementations (including systems, methods, apparatus, kits, and/or the like) disclosed herein without departing from the scope of the present disclosure. Thus, reference to a specific feature in relation to one embodiment and/or implementation should not be construed as being limited to applications only within that embodiment and/or implementation.

The headings used herein are for organizational purposes only and are not meant to be used to limit the scope of the description or the claims. To facilitate understanding, like reference numerals have been used, where possible, to designate like elements common to the figures. Furthermore, where possible, like numbering of elements have been used in various figures. Furthermore, alternative configurations of a particular element may each include separate letters appended to the element number.

All publications, patent applications, patents or other references mentioned herein are incorporated by reference for in their entirety.

There is a strong commercial need for inexpensive, disposable, and/or point-of-use sensors, particularly with rapid response (or diagnostic) time, especially for monitoring disease biomarkers or environmental contaminants (e.g., in drinking water). Sensors that employ smart polymer hydrogels as recognition elements can be tailored to detect almost any target analyte, but often suffer from long response times. We describe here fabrication processes that can be used to manufacture low-cost, disposable, and/or point-of-use hydrogel-based microfluidics sensors with short response times. Rapid hydrogel response rate is achieved by fabricating arrays of smart hydrogels that have large surface area-to-volume ratios.

The present disclosure relates to the potential use of mask-templated UV photopolymerization to produce microscopic smart hydrogel pillars with large surface area-to-volume ratios and, consequently, fast response rates. Arrays of (regularly spaced) smart hydrogel pillars can be fabricated inside sub-millimeter channels located within microfluidics devices. Specifically, in some embodiments of the present disclosure (e.g., a fabrication process), mask-templated UV photopolymerization is used to produce arrays of smart hydrogel pillars inside sub-millimeter channels located upon microfluidics devices. When these pillars contact aqueous solutions containing a target analyte, they swell or shrink, thereby changing the resistance of the microfluidic channel to ionic current flow when a small bias voltage is applied to the system. Hence resistance measurements can be used to transduce hydrogel swelling changes into electrical signals. With the addition of (portable) potentiostat that can optionally be operated using a smartphone or a laptop, the system can be suitable for point of use.

For potential use in chemical sensing, microfluidic devices offer advantages such as potentially being low cost and requiring only small sample volumes. Thus, the present disclosure also relates to a novel method for chemical sensing transduction using smart hydrogel pillars that we call resistive channel sensing. In this sensing approach, smart hydrogel pillars are fabricated within the main channel of a microfluidics device. The microchannel is then filled with phosphate buffered saline (PBS) solution to create a conductive path for ionic current. A DC voltage of 0.3 volts is applied to the system through the contact pads (the electrodes), which are in contact with the solution, and the induced ionic current through the channel is measured as an electrical current between the electrodes.

Once the analyte reaches the smart hydrogel pillars, the pillars shrink or swell, thereby changing the resistance in the main microchannel that results in a change of the measured current. This sensing approach is similar to the well-studied technique known as microfluidic resistive pulse sensing (MRPS), in which changes in the electrical resistance of a microfluidic channel are used to determine the size of nanoparticles that pass through a microfluidic channel. The present disclosure illustrates the feasibility of fabricating microscopic smart hydrogel pillar arrays with large surface area-to-volume ratios inside microfluidics channels, and secondly to determine the reduction in the response time that can be attributed to the use of smart hydrogel pillars within microfluidic sensors.

The present disclosure also presents sensing results obtained using arrays of regularly spaced hydrogel pillars within two different microfluidic channels, with the pillars having surface area-to-volume ratios of 40 mm⁻1 and 13.3 mm⁻1, respectively. The sensor response time is shown to decrease with an increase in surface area-to-volume ratio.

### Fabrication of Microfluidic Channels

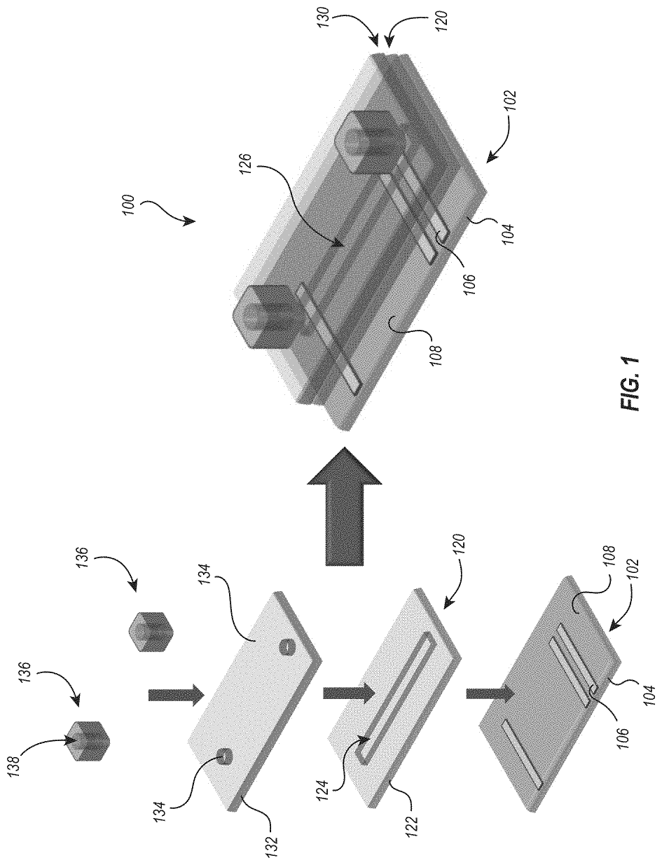

It will be appreciated that microfluidics devices and/or microfluidic channels thereof according to embodiments of the present disclosure can be manufactured or formed through a variety of methods. Several fabrication approaches are known in the art and compatible with the embodiments disclosed and described herein. FIG. 1 shows an illustration of the assembly of an illustrative microfluidics device 100 (for in situ patterning of hydrogel pillars, as described below). The device can be manufactured using a low-cost fabrication approach with the microfluidic channels fabricated employing a computer controlled cutting plotter. The illustrative channel designs were created in AutoCAD (Version: 2016; Autodesk, Inc., San Rafael, Calif., USA) and then cut with the knife plotter (Model CAMEO 2; Silhouette America Inc.).

The microfluidics device 100 of FIG. 1 comprises three main layers—a bottom layer 102, a center layer 120, and a top layer 130. The bottom layer 102 in the device 100 comprises a base substrate 104, comprising a (rectangular) piece of polycarbonate (40 mm×75 mm×0.25 mm), with electrodes 106 (e.g., silver paste electrodes) (MG Chemical) (1 mm×25 mm×0.04 mm) stenciled or affixed onto a surface 108 of the base 104. As illustrated in FIG. 1, one electrode 106 or multiple electrodes 106 can be placed at opposing ends of the base 104. The center layer 120 comprises an adhesive film layer 122 (e.g., polyvinyl chloride (PVC) adhesive film) that binds the (bottom and top) layers together and that also serves as the microchannel structure. Specifically, an elongated channel 124 is cut through the adhesive film 122 to form the microchannel 126 in the assembled device 100. The channel 124 and/or microchannel 126 formed thereby can have a length of about 35 mm, a width of about 1.6 mm, and a depth of about 50 μm, in some embodiments. Accordingly, the center (adhesive) layer 120 can have a thickness of about 50 μm, in some embodiments. The top layer 130 comprises a covering 132, comprising another (rectangular) piece of polycarbonate (25 mm×75 mm×0.25 mm), with holes 134 punched or extending therethrough (and serving as inlet/outlet ports to access the microfluidic channel 126 in the assembled device 100). The top layer 130 can be slightly smaller (width wise) than the bottom layer 102 to allow access to the electrodes 106 for measurement. To make interfacing with the device 100 and/or microfluidic channel 126 simple or convenient, connectors 136 (e.g., for attaching microfluidic tubing) can be attached to the top layer 130 over the holes 134. The connectors 136 can comprise a block of PDMS having an access port 138 extending therethrough.

UV Photopolymerization of Smart Hydrogel Pillar Arrays within Microfluidic Channels

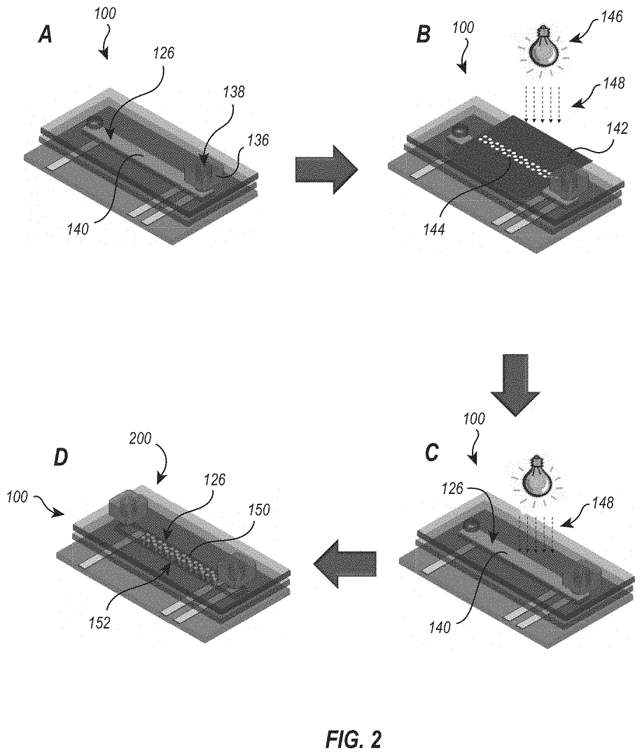

FIG. 2 demonstrates an illustrative method of forming or patterning smart hydrogel features (e.g., an array of smart hydrogel pillars) in a microfluidic channel. For ease of illustration, FIG. 2 depicts the microfluidics device 100 of FIG. 1 (modified, as indicated). An array of smart hydrogel features (e.g., an array of distinct, spaced-apart, smart hydrogel pillars extending transverse across the microfluidic channel) can be fabricated inside an enclosed microchannel 126 of the microfluidics device 100 using an in situ photopolymerization technique, described below.

Once the 3-layer microfluidic device 100 is cut and assembled, a pre-gel (fluid) hydrogel solution 140 (described in further detail, below), is introduced (e.g., using capillary forces) into the microchannel 126 via the access port 138 in the connectors 136 and the hole 134 of top layer 130 (or the covering 132 thereof), as shown in FIG. 2(A). Illustratively, a 13 wt % pre-gel (fluid) hydrogel solution containing 80 mol % acrylamide, 8 mol % 3-acrylamidophenylboronic acid, 10 mol % N[3-(dimethylamino)propyl]methacrylamide, 2 mol % N,N′-methylenebisacrylamide and a free-radical photoinitatior can be fluidly introduced into microchannel 126. Illustratively, the smart hydrogels disclosed herein, comprised of 13 wt % of the monomers, were copolymers containing 80 mol % acrylamide from Fisher Scientific (Hampton, N.H., USA), 8 mol % 3-acrylamidophenylboronic acid from Achemo (Hong Kong, China), 10 mol % N-[3-(dimethylamino)propyl]methacrylamide from Polysciences Inc. (Warrington, Fla., USA), and 2 mol % N,N′-methylenebisacrylamide from Sigma-Aldrich (St. Louis, Mo., USA).

Subsequently, as shown in FIG. 2(B), a (dark field) photomask 142 having aperture(s) 144 arranged in the desired feature (e.g., pillar array) design is placed over the microchannel 126. Illustratively, the apertures 144 in the phot mask 142 can be round (to form cylindrical pillars) or any other suitable geometric shape (e.g., oval, square, rectangular, etc.). Photo patterning of the array is accomplished by directing collimated UV light 148 from a UV light source 146 through the apertures 144 to polymerize the hydrogel 140 to form (solid or semi-solid) smart hydrogel pillars 150 within the microchannel 126. Illustratively, the hydrogels were polymerized via cros slinking copolymerization using lithium phenyl-2,4,6-trimethylbenzoylphosphinate from Sigma-Aldrich (St. Louis, Mo., USA) as the UV free radical initiator. The light source was a collimated Hg-vapor lamp. While patterning the hydrogel pillars, a dark field chromium photomask with the desired pillars pattern was placed over the channel. Collimated UV light from a mask aligner (Model 206; OAI, San Jose, Calif., USA), with an initial intensity of 13.5 W/cm2 and an exposure time of 5.5 s, was used to polymerize the hydrogel to form pillars within the microchannel.

Illustratively, after this first photo patterning is complete, the mask 142 is removed, as shown in FIG. 2(C), and the entire microchannel 126 (containing (unpolymerized) hydrogel pre-gel hydrogel solution 140 and (at least partially polymerized) smart hydrogel pillars 150 (see FIG. 2(D)) is flood exposed to the UV light for another quarter of the previous masked exposure time. Illustratively, 1.5 s of UV exposure was flood applied to the channel itself, after the photo patterning was complete and the mask was removed. In certain embodiments, this additional step may be necessary to polymerize a thin hydrogel layer across the channel to enhance adhesion of the hydrogel pillars to the channel and to keep their regular arrangement. Specifically, the shortened, flood exposure process created a thin film of hydrogel between the pillars to keep the pillars from being flushed away during the introduction of analyte solutions. Without being bound to any theory, when this step was not carried out in the current embodiment, it was observed that the patterned pillars did not keep their locations in the channel and were easily flushed out by the surrounding flow. Moreover, the UV light intensity decreased slightly from its initial value at the beginning of the experiments. Hence, the exposure time was adjusted accordingly to ensure a constant exposure dose for all experiments.

The unpolymerized or incompletely polymerized hydrogel (solution) can then be, optionally, flushed or washed from the microchannel by irrigating the channel with a (wash) buffer, solution, or water, leaving only the (polymerized) array 152 of smart hydrogel features (pillars) 150 in the microfluidic channel 126. The resulting device, a microfluidics sensing device 200, comprises the microfluidics device 100 and the array 152 of smart hydrogel features (pillars) 150 in the microfluidic channel 126 thereof. Illustratively, the pillars 150 can be substantially cylindrical and, optionally, regularly spaced apart, due to the configuration (e.g., shape and spacing) of the apertures 144 in the photo mask 142.

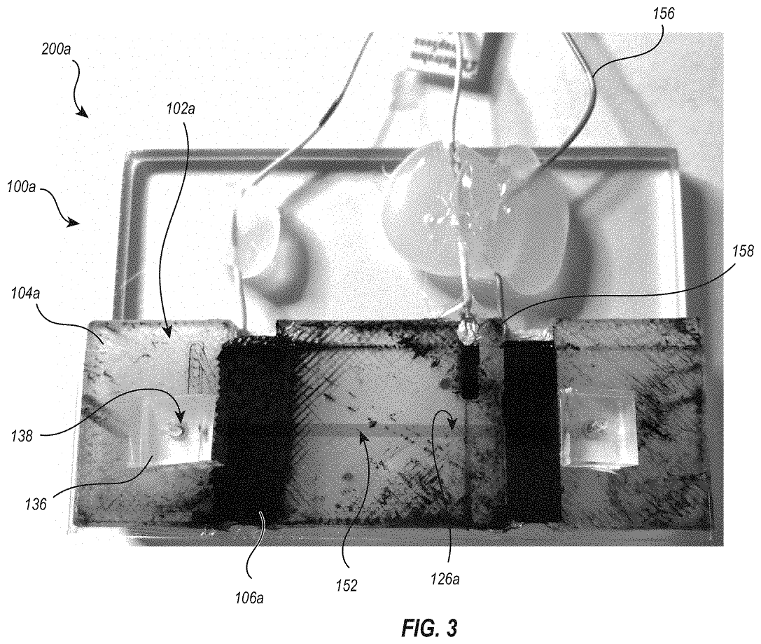

An alternative microfluidics sensing device 200a is illustrated in FIG. 3. The microfluidics sensing device 200a is similar in many respects to sensing device 200. For example, sensing device 200a similarly comprises a microfluidics device 100a and an array 152 of smart hydrogel features (pillars) 150 in a microfluidic channel 126a. However, a bottom layer 102a of the device 100a comprises a 3D printed base substrate 104a, illustratively comprising a non-conductive polylactic acid (PLA) (white) material and conductive PLA (black) 106a, as an electrode material (instead of (silver) electrodes, as in device 100). The microchannel 126a can be raised above the upper surface of the base substrate 104a or recessed into (or below) the upper surface of the base substrate 104a. Illustratively, the microchannel 126a (or microchannel network) can comprise one or more (thin) layer(s) (e.g. sheet(s)) of polycarbonate or other material (e.g., polymer). The conductive PLA (black) 106a contacts, interacts, and/or intersects the microchannel 126a (so as to be in electrical communication therewith). The pre-gel solution can be introduced through hole(s) 138 of connector(s) 136 and polymerized as described previously.

Devices of the present disclosure can be connected to a potentiostat (not shown) via electrical connectors (or wires) 156 attached to the device so as to be in electrical communication with the microchannel 126, 126a, for operation.

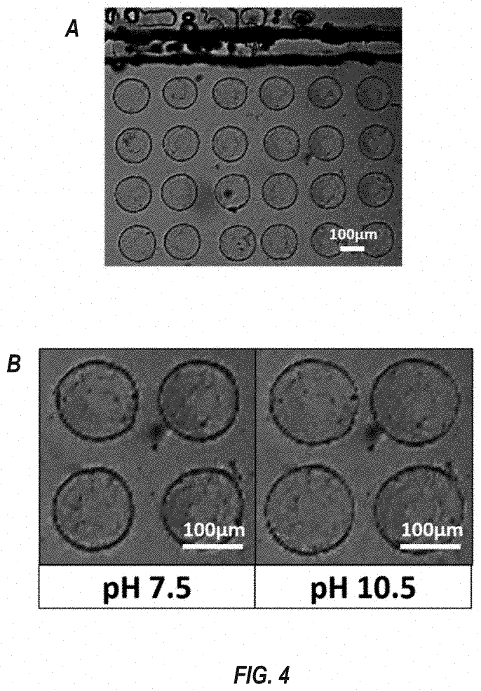

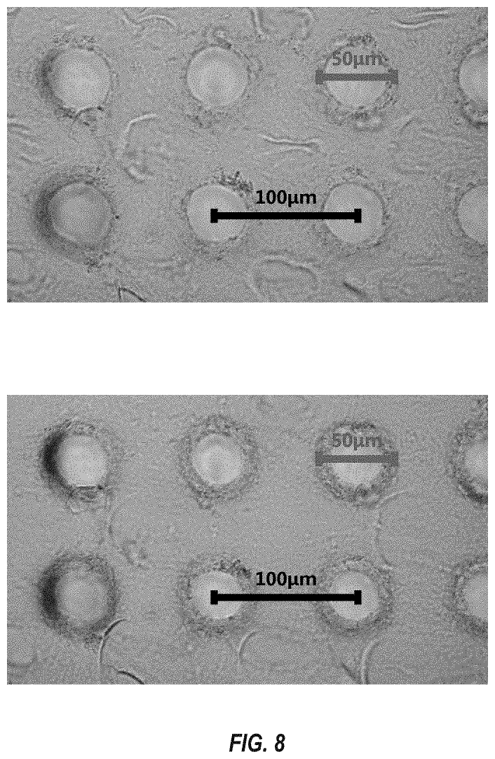

Regardless of the specific implementation, the hydrogel surface area-to-volume ratio can be varied by fabricated arrays comprising features (e.g., pillars) of various dimensions. An illustrative array 152 can have a plurality of pillars 150 with respective diameters (as defined by the UV mask) of about 100 μm, and pillar height (as defined by the height of the microchannel) of about 50 μm, and a spacing of about 200 μm between the centers of the pillars 150 (see FIG. 4). The fraction of the total (filled) microfluidic channel area or volume occupied by the pillars 150 is about 19.6% in this embodiment. In an alternative embodiment (not shown), the array can have pillar diameters of about 300 μm, with a spacing of about 600 μm between the centers of the pillars 150. However, the pillar height (about 50 μm) and the fraction of the total area occupied by the pillars (about 19.6%) were about the same in both arrays. In another embodiment, the array can have pillar diameters of about 50 μm, with a spacing of about 100 μm between the centers of the pillars 150 (see FIG. 8).

### Response of the Hydrogel Pillars to Cyclic Changes in pH

In proof-of-concept response tests, the microfluidics sensor of FIG. 2 was subjected to cyclic changes in pH between 7.5 and 10.5. The hydrogel studied here contains both cationic tertiary amines and anionic phenylboronic acid moieties. However, the net hydrogel charge is negative at pH 7.5, and even more so at pH 10.5. Hence the hydrogel is expected to swell when pH is increased from 7.5 to 10.5. To make this swelling change easier to visualize with an optical microscope, we performed the pH response tests in a low ionic strength saline buffer ( 1/12× PBS). This reduction in salinity increases the pillar diameter at all pH values, because addition of salt causes hydrogels to shrink by reducing the environmental chemical potential value of water.

A syringe pump (Model 780212; KD Scientific Inc., Holliston, Mass., USA) was used to withdraw analyte solutions from one of two reservoirs (pH 7.5 and pH 10.5 in 1/12× PBS) and into the microfluidic sensors. For the sensor containing the smaller pillars, the syringe pump connection was switched between the reservoirs every 30 min, and the flow rate was 10 μL/min. For the sensor containing the larger pillars, the syringe pump connection was switched between the reservoirs every 60 min, and the flow rate was 10 μL/min. This flow rate implies a Reynolds number value of less than 100; the ionic current flow attributable to this flow is of order 1 to 10 nA. The ionic current within the main microfluidics channel was measured using a potentiostat (EmStat3+) using a three-electrode configuration. One electrode pad was connected to the working electrode, while the other two were connected to the counter electrode and reference electrode pads. The system operates by applying a small bias voltage and reading the resulting current across the microchannel. The Chronoamperometry method was used to record the current data in PSTrace (Verson 5.2, Houten, The Netherlands), using a software application that came with EmStat3+. A 60 s pretreatment with a constant DV voltage of 0.3 volts was applied before data collection; the same DC voltage was then applied again throughout the entire experimental period.

The targeted solution was introduced into the microfluidic channel using the syringe pump with a flow rate of 10 μL/min for at least 20 min before imaging the pillars.

To measure the time-dependent response of the pillar diameter, a digital camera (Model LCMOS05100KPA; ToupTek, Hangzhou, China), installed on a polarizing binocular microscope (Model G508, Unico, Dayton, Ohio, USA), was used to take photos of the sensor pillar array every 30 s. The syringe pump was used to flow 1/12× PBS into the sensor at a flow rate of 10 μL/min, with the pH value of this solution increasing with time from 7.5 to 10.5 while photos were being taken. The photos were then analyzed using the oval tool from Image J to calculate the diameter of the pillar.

FIG. 4A shows a micrograph of the array of smart hydrogel pillars as viewed top down in 1/12× PBS buffer at pH 7.5. This micrograph confirms that we succeeded in fabricating a regularly spaced array of smart hydrogel pillars within a microfluidics channel. FIG. 4B compares the pillar diameter at pH 7.5 and 10.5. The pillars swell with increase in pH for the reasons discussed above.

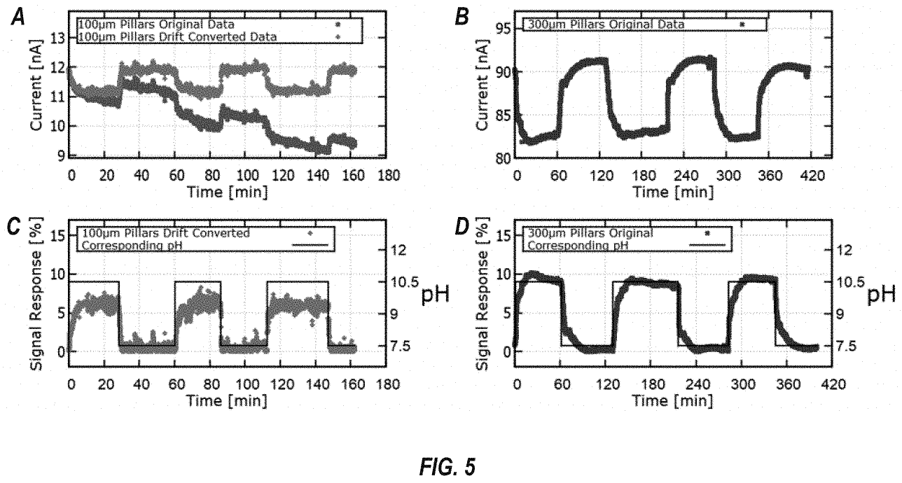

When the hydrogel pillar diameter changes due to the change in pH, this changes the value of the ionic current detected by the potentiostat at fixed voltage, as shown by the results presented in FIG. 5. FIG. 5 shows the time-dependent behavior of the sensor current at fixed voltage as the pH value is periodically changed between 7.5 and 10.5. Results are presented for two different devices, one containing pillars of diameter 100 μm, and the other containing pillars of diameter 300 μm. At the higher pH value, the hydrogel pillars swell, which corresponds to a minimum in the value of the ionic current. The conductance of the microfluidics channel is proportional to both the ion concentration and the cross-sectional area available for current flow. Since the ionic strength was fixed at 25 mOsm/kg in these experiments, the oscillation in current observed in FIG. 5 can be attributed to changes in the microfluidics channel cross-sectional area that occur as the pillars shrink and swell. FIG. 5 also contains results for the time-dependent Signal Response %, defined as

$$Signal Response \% = \frac{{I}_{base} - I}{{I}_{base}} \times 100 \% \qquad Equation ( 1 )$$

where I is the value of the ionic current at a given time t, and Ibase is the maximum current value measured at times at which the pH value equals 7.5. The value of Ibase was substantially different for the two devices studied (FIG. 5), probably due to variabilities in the device fabrication procedure. Nonetheless, the signal response, calculated as a percentage (Equation (1)) was quite similar for the two devices studied (FIG. 5). Most of the pH response of the smart hydrogel studied here occurs near pH 7, because this is close to the pKa value of PBA inside polyampholytic hydrogels. Hence it the sensor studied here could probably not be used for pH values below 6 or above 8, unless we changed the hydrogel. Based upon the results in FIG. 5, we estimate that the sensor has a resolution of about 0.1 pH units near pH 7.

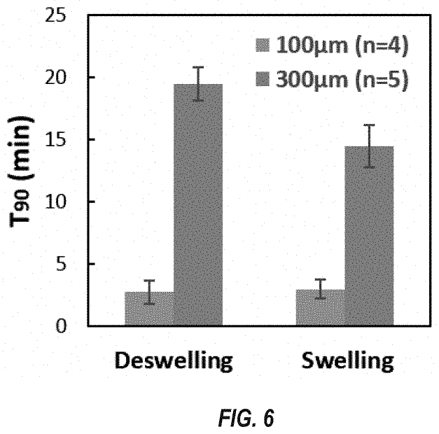

The pH response data in FIG. 5 was used to calculate the T90 response times of the two sensor devices studied. The results are presented in FIG. 5. For both devices, the swelling response time is shorter than the shrinking response time. This may potentially be explained as follows. When a hydrogel starts to shrink, it shrinks first at its outer surface, thereby creating an outer surface film with a low permeability that retards further diffusion of the target analyte into the hydrogel. This, of course, tends to increase the hydrogel response time. For both swelling and shrinking response, FIG. 6 shows that the response time is smaller for sensors containing smaller diameter hydrogel pillars. Comparison is made in FIG. 6 between T90 response times obtained using pillars of diameter 100 μm and diameter 300 with surface area-to-volume ratios of 40 mm⁻¹ and 13.3 mm^{-1,} respectively. The increase in the surface area-to-volume ratio by a factor of 3 is observed to reduce the sensor response time, averaged over both swelling and shrinking response times, by a factor of approximately 7.

The smart hydrogels disclosed herein studied in this work were both glucose- and pH-responsive. It will be appreciated that smart hydrogels can be optimized, as known in the art, to make the hydrogels responsive to virtually any analyte of interest.

### Response of the Hydrogel Pillars to Changes in Ionic Strength

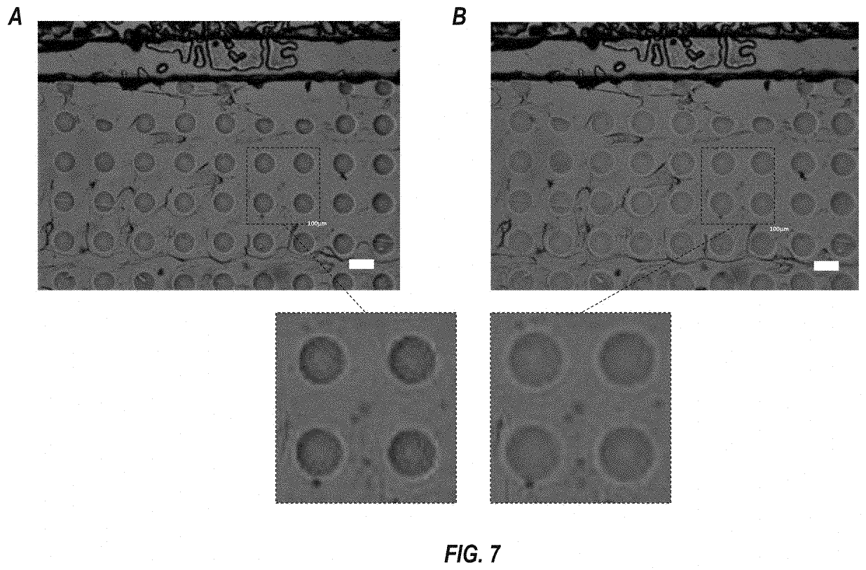

FIG. 7 illustrates a top-down view of an illustrative array of smart hydrogel pillars showing the size change due to changes in environmental ionic strength: (A) smaller diameter smart hydrogel pillars surrounded by lx PBS solution. (B) larger diameter smart hydrogel pillars surrounded by 0.33× PBS solution. Pillars size difference is approximately 10%. FIG. 8 similarly illustrates pillars before (A) and after (B) shrinking in response to stimulus (i.e. ionic strength, pH, glucose concentration, analyte binding , etc.).

### Illustrative Smart Hydrogel Containing Microfluidics Sensing Device and Method

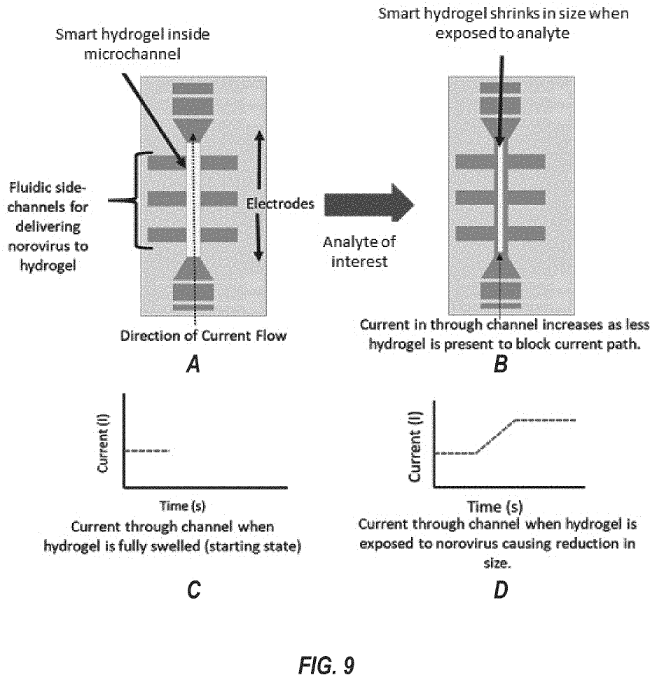

FIG. 9 illustrates a schematic of a microfluidics sensing device with smart hydrogel for detecting analytes of interest in solution using resistive channel sensing (RCS). The device is designed to detect changes in the size of the hydrogel as it shrinks (or swells) when exposed to an analyte (e.g., when the analyte binds to the hydrogel). The measurement is made using current measurements through the (center of the) microchannel. Using a four-electrode configuration, for example, a small (input) voltage or voltage bias is applied (across the microchannel), and (output) current is measured. In the illustrative starting state depicted in FIG. 9(A), the hydrogel is fully swelled (e.g., in an aqueous fluid (or solution) comprising PBS), which reduces the current that can pass through the central microchannel. As fluid (e.g., PBS solution or water) with the analyte is delivered through the side channels to the central channel, the hydrogel with begin to shrink, allowing more current to travel through the microchannel (B). A plot of current vs. time is shown for each state (C) and (D). This method allows for a simple electronic output for monitoring hydrogel sensing. FIG. 8 shows an example of a hydrogel shrinking from a stimuli (e.g., analyte exposure). The hydrogel can also or alternatively be engineered to expand in response to stimuli (e.g., exposure to certain analyte(s)), which would give currents or current changes in the opposite direction of those shown.

### CONCLUSION

In the present disclosure, we disclose a method for fabricating low-cost and fast-responding smart hydrogel sensors inside microfluidics channels using soft material microfabrication techniques. The use of photolithographic methods to create micrometer scaled smart hydrogel structures inside a microchannel reduces the cost for this device and removes the need for cleanroom facilities. While in this work we did use a UV source from a mask aligner, without being bound to any theory, a low-cost collimated UV source (such as from Omnicure Inc.) would have been sufficient to create the micropillar arrays.

In the present disclosure, arrays of (pH-responsive, glucose-responsive, etc.) smart hydrogel pillars were fabricated within a microfluidics channel with large surface area-to-volume ratios (e.g., at least 40 mm⁻¹). The pH response of these pillars was transduced into an electrical signal using a novel technique termed resistive channel sensing. The electronic signal obtained using this microfluidic pH sensor was shown to be reversible and reproducible. The response time of the microfluidic pH sensor was shown to decrease with increase in the surface area-to-volume ratio of the hydrogel pillars. The fabrication process presented here is a low-cost way to solve a long-standing problem of smart hydrogel analytical devices: namely, their long response times.

While the foregoing detailed description makes reference to specific exemplary embodiments, the present disclosure may be embodied or implement in other specific forms without departing from its spirit or essential characteristics. Accordingly, the described embodiments, implementations, aspects, and/or features are to be considered in all respects only as illustrative and/or exemplary, and not restrictive. For instance, various substitutions, alterations, and/or modifications of the inventive features described and/or illustrated herein, and additional applications of the principles described and/or illustrated herein, which would occur to one skilled in the relevant art and having possession of this disclosure, can be made to the described and/or illustrated embodiments without departing from the spirit and scope of the invention as defined by the appended claims. The scope of the invention is, therefore, indicated by the appended claims rather than by the foregoing description.

It will also be appreciated that various features of certain embodiments can be compatible with, combined with, included in, and/or incorporated into other embodiments of the present disclosure. For instance, systems, methods, and/or products according to certain embodiments of the present disclosure may include, incorporate, or otherwise comprise features described in other embodiments disclosed and/or described herein. Thus, disclosure of certain features relative to a specific embodiment of the present disclosure should not be construed as limiting application or inclusion of said features to the specific embodiment. In addition, unless a feature is described as being requiring in a particular embodiment, features described in the various embodiments can be optional and may not be included in other embodiments of the present disclosure. Moreover, unless a feature is described as requiring another feature in combination therewith, any feature herein may be combined with any other feature of a same or different embodiment disclosed herein.

The scope of any invention(s) disclosed and/or described herein is indicated by the appended claims rather than by the foregoing description. The limitations recited in the claims are to be interpreted broadly based on the language employed in the claims and not limited to specific examples described in the foregoing detailed description, which examples are to be construed as non-exclusive and non-exhaustive. All changes which come within the meaning and range of equivalency of the claims are to be embraced within their scope.

### REFERENCES

The present disclosure makes reference to a number of publications and other references, each of which is incorporated in its entirety by specific reference.
Gehrke, S. H. Synthesis, equilibrium swelling, kinetics, permeability and applications of environmentally responsive gels. In Responsive Gels: Volume Transitions II; Springer: Berlin, Germany, 1993; pp. 81-144.
Peppas, N. A.; Hilt, J. Z.; Khademhosseini, A.; Langer, R. Hydrogels in biology and medicine: From molecular principles to bionanotechnology. Adv. Mater. 2006, 18, 1345-1360.
Richter, A.; Paschew, G.; Klatt, S.; Lienig, J.; Arndt, K. F.; Adler, H. J. Review on hydrogel-based pH sensors and microsensors. Sensors 2008, 8, 561-581.
Eddington, D. T.; Beebe, D. J. Flow control with hydrogels. Adv. Drug Deliv. Rev. 2004, 56, 199-210.
Lin, G.; Chang, S.; Kuo, C. H.; Magda, J.; Solzbacher, F. Free swelling and confined smart hydrogels for applications in chemomechanical sensors for physiological monitoring. Sens. Actuators B Chem. 2009, 136, 186-195.
Beebe, D. J.; Moore, J. S.; Bauer, J. M.; Yu, Q.; Liu, R. H.; Devadoss, C.; Jo, B. H. Functional hydrogel structures for autonomous flow control inside microfluidic channels. Nature 2000, 404, 588-590.
Hatch, A.; Hansmann, G.; Murthy, S. K. Engineered alginate hydrogels for effective microfluidic capture and release of endothelial progenitor cells from whole blood. Langmuir 2011, 27, 4257-4264.
Kim, S. M.; Lee, B.; Yoon, H.; Suh, K. Y. Stimuli-responsive hydrogel patterns for smart microfluidics and microarrays. Analyst 2013, 138, 6230-6242.
Saleh, O.A.; Sohn, L.L. An artificial nanopore for molecular sensing. Nano Lett. 2003, 3, 37-38.

Bartholomeusz, D.; Boutté, R.; Gale, B. Xurography: Microfluidic prototyping with a cutting plotter. In Lab on a Chip Technology: Fabrication and Microfluidics; Caister Academic Press: Poole, UK, 2009; Volume 1, pp. 65-82.

Mohanty, S. K.; Kim, D.; Beebe, D. J. Do-it-yourself microelectrophoresis chips with integrated sample recovery. Electrophoresis 2006, 27, 3772-3778.
Nguyen, T.; Magda, J. J.; Tathireddy, P. Manipulation of the Isoelectric Point of Polyampholytic Smart Hydrogels In Order to Increase the Range and Selectivity of Continuous Glucose Sensors. Sens. Actuators B 2018, 255, 1057-1063.
Lin, G.; Chang, S.; Hao, H.; Tathireddy, P.; Orthner, M.; Magda, J.; Solzbacher, F. Osmotic swelling pressure response of smart hydrogels suitable for chronically implantable glucose sensors. Sens. Actuators B Chem. 2010, 144, 332-336.
Rasband, W. S.; ImageJ, U.S. National Institutes of Health, Bethesda, Md., USA, 1997-2016. Available online: https://imagej.nih.gov/ij/.

What is claimed is:

1. A method of sensing an analyte of interest, the method comprising:
applying a current or voltage across a microfluidic channel of a microfluidics sensor device, the microfluidic channel comprising or having disposed therein:
an ion-conducting or electrically conductive fluid medium; and
an array of smart hydrogel features disposed in the medium;
introducing a fluid sample into the microfluidic channel, the fluid sample comprising the analyte; and
measuring a change in an output reading of the applied current or voltage as the array of smart hydrogel features is exposed to the analyte, wherein:
exposing the array of smart hydrogel features to the analyte causes a change in size of one or more of the smart hydrogel features;
the change in the size of the one or more smart hydrogel features causes a change in resistance across the microfluidic channel; and
the change in resistance across the microfluidic channel causes the change in the output reading of the applied current or voltage,
such that the change in the output reading of the applied current or voltage indicates presence of the analyte in the sample.

2. The method of claim 1, wherein each of the smart hydrogel features in the array has a surface area-to-volume ratio greater than or equal to 13.3 mm⁻¹.

3. The method of claim 1, wherein the array comprises a plurality of spaced-apart smart hydrogel pillars.

4. The method of claim 3, wherein the pillars are substantially cylindrical, each of the pillars optionally having a diameter of less than or equal to about 300 μm and/or being separated from a nearest neighboring pillar by at least 50 μm.

5. The method of claim 1, wherein about 10% to about 30% of microfluidic channel volume or area is occupied by the smart hydrogel features.

6. The method of claim 1, wherein the microfluidic channel comprises an at least partially tubular or enclosed conduit, the smart hydrogel features extending across the conduit.

7. The method of claim 1, wherein introducing the analyte into the microfluidic channel changes pH of the medium, thereby causing the change in the size of the one or more smart hydrogel features.

8. The method of claim 1, wherein the applied current or voltage is a fixed voltage and the change in the output reading of the applied current or voltage is a change in a value of ionic current, wherein the change in the value of the ionic current is detected by a potentiostat applying the fixed voltage.

9. The method of claim 1, wherein the medium comprises an aqueous salt solution.

10. The method of claim 1, further comprising continuously flowing the medium through the microfluidic channel.

11. A method of sensing an analyte, the method comprising:
exposing the analyte to an array of smart hydrogel features disposed in a microfluidic channel; and
measuring a change in a current or voltage bias across the microfluidic channel, wherein the change in the current or voltage bias indicates exposure of the array of smart hydrogel features to the analyte.

12. A microfluidics sensor device, comprising a microfluidic channel having an array of smart hydrogel features disposed therein.

13. The microfluidics sensor device of claim 12, wherein:
each of the smart hydrogel features in the array has a surface area-to-volume ratio greater than or equal to 13.3 mm^{31 1};
each of the smart hydrogel features is optionally separated from a nearest neighboring smart hydrogel features by at least 50 μm;
about 10% to about 30% of microfluidic channel volume or area is occupied by the smart hydrogel features; and/or
the array comprises a plurality of spaced-apart smart hydrogel pillars, the pillars optionally being substantially cylindrical, each of the pillars optionally having a diameter of less than or equal to about 300 μm.

14. A method of manufacturing the microfluidics sensor device of claim 12, the method comprising:
introducing a fluid and/or pre-gel hydrogel solution into the microfluidic channel;
positioning a photomask over the microfluidic channel, the photomask comprising an array of apertures;
directing collimated UV light through the apertures an into the microfluidic channel for a first period of time, thereby at least partially polymerizing portions of the hydrogel to form the array of smart hydrogel features within the microfluidic channel;
removing the photomask;
exposing the microfluidic channel to UV light for a second period of time; and
irrigating the microfluidic channel to remove unpolymerized hydrogel, thereby forming the array of smart hydrogel features within the microfluidic channel.

15. The method of claim 14, further comprising:
3D printing a bottom layer of the microfluidics sensor device, the bottom layer comprising a microchannel; and
covering the microchannel with a non-opaque top layer, thereby forming the microfluidic channel.

16. The method of claim 15, wherein the bottom layer comprises a first, electrically non-conductive polymer and a second, electrically conductive polymer, the second polymer intersecting the microchannel so as to be in electrical communication therewith.

17. The method of claim 16, wherein the first polymer and/or the second polymer comprises a polylactic acid (PLA).

18. The method of claim 15, wherein the bottom layer comprises a first electrode disposed at a first end of the microchannel and a second electrode disposed at an opposing second end of the microchannel, the first electrode and the second electrode comprising an electrically conductive polymer, optionally comprising a polylactic acid (PLA).

19. The method of claim 14, wherein the first period is about 3 seconds to about 8 seconds and the second period is about 10% to about 40% of the first period.

20. The method of claim 14, wherein the microchannel is raised above an upper surface of the bottom layer.
